(19) United States
(12) Patent Application Publication
(10) Pub. No.: US 2025/0015025 A1
(43) Pub. Date: Jan. 9, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Junyeong Heo, Suwon-si (KR); Sera Lee, Suwon-si (KR); Yeongkwon Ko, Suwon-si (KR)

(21) Appl. No.: 18/431,869

(22) Filed: Feb. 2, 2024

(30) Foreign Application Priority Data
Jul. 7, 2023 (KR) 10-2023-0088238
Jul. 13, 2023 (KR) 10-2023-0091163

(51) Int. Cl. H01L 23/00; H01L 23/48

(52) U.S. Cl. CPC H01L 24/05; H01L 23/481; H01L 24/03; H01L 24/11; H01L 24/13; H01L 24/16; H01L 24/32; H01L 24/73; H01L 2224/0361; H01L 2224/0401; H01L 2224/05541; H01L 2224/05557; H01L 2224/11; H01L 2224/13; H01L 2224/16145; H01L 2224/32145; H01L 2224/73204

(57) ABSTRACT

A semiconductor package includes a substrate, a dielectric structure disposed on the substrate, a via structure that penetrates the substrate and the dielectric structure, and a pad structure that is in contact with the via structure. The dielectric structure includes a first part and a second part disposed on the first part. The second part of the dielectric structure is disposed between the via structure and the pad structure. A top surface of the second part of the dielectric structure is coplanar with a top surface of the via structure.

### CROSS-REFERENCE TO RELATED APPLICATIONS

This U.S. nonprovisional application claims priority under 35 U.S.C. § 119 to Korean Patent Applications No. 10-2023-0088238, filed on Jul. 7, 2023, and Korean Patent Applications No. 10-2023-0091163, filed on Jul. 13, 2023, in the Korean Intellectual Property Office, the disclosures of which are hereby incorporated by reference in their entirety.

### TECHNICAL FIELD

The present inventive concepts relate to semiconductors, and more particularly, to a semiconductor package and a method of fabricating the same.

### DISCUSSION OF THE RELATED ART

Integrated circuit (IC) chips are generally mounted within a semiconductor package to protect the chip and help it be connected for use within electronic products. A semiconductor package, including the semiconductor chip disposed therein, is mounted on a printed circuit board and bonding wires or bumps are used to electrically connect the semiconductor chip, within the semiconductor package, to the printed circuit board.

### SUMMARY

A semiconductor package includes a substrate. A dielectric structure is disposed on the substrate. A via structure penetrates the substrate and the dielectric structure. A pad structure is disposed on the via structure. The pad structure includes a first bottom surface that is in contact with the via structure, a second bottom surface at a level that is lower than a level of the first bottom surface, and an inner sidewall that connects the first bottom surface to the second bottom surface. A portion of the dielectric structure is between the via structure and the inner sidewall of the pad structure.

A semiconductor package includes a substrate, a dielectric structure disposed on the substrate, a via structure that penetrates the substrate and the dielectric structure, and a pad structure in contact with the via structure. The dielectric structure includes a first part and a second part disposed on the first part. The second part of the dielectric structure is between the via structure and the pad structure. A top surface of the second part of the dielectric structure is coplanar with a top surface of the via structure.

A semiconductor package includes a substrate. A dielectric structure is disposed on the substrate. A via structure penetrates the substrate and the dielectric structure. A pad structure is disposed on the via structure. A bump is in contact with the pad structure. The dielectric structure includes a first part and a second part disposed on the first part. The pad structure includes a first bottom surface that is in contact with the via structure. A second bottom surface is at a level that is lower than a level of the first bottom surface. An inner sidewall connects the first bottom surface to the second bottom surface. The first part of the dielectric structure is in contact with the second bottom surface of the pad structure. The second part of the dielectric structure is in contact with the inner sidewall of the pad structure and the first bottom surface of the pad structure. The via structure is in contact with the first bottom surface of the pad structure.

A method of fabricating a semiconductor package includes forming a preliminary substrate. A preliminary via structure is formed surrounded by the preliminary substrate. A portion of the preliminary substrate is removed to expose the preliminary via structure. A preliminary dielectric structure is formed on the preliminary via structure. A portion of the preliminary dielectric structure is removed and a portion of the preliminary via structure is removed to form a dielectric structure and a via structure, A pad structure is formed on the dielectric structure and the via structure. The dielectric structure includes a first part and a second part. The second part of the dielectric structure is at least partially surrounded by the pad structure.

### BRIEF DESCRIPTION OF DRAWINGS

FIG. 1A is a cross-sectional view showing a semiconductor package according to some embodiments.

FIG. 1B is an enlarged cross-sectional view showing section A of FIG. 1A.

FIG. 2 is an enlarged cross-sectional view showing a semiconductor package according to some embodiments.

FIGS. 3A to 31 are cross-sectional views showing a method of fabricating a semiconductor package according to FIG. 1A.

FIG. 4 is a cross-sectional view showing a semiconductor package according to some embodiments.

FIG. 5 is a cross-sectional view showing a semiconductor package according to some embodiments.

### DETAILED DESCRIPTION OF EMBODIMENTS

It will be hereinafter discussed a semiconductor package and a method of fabricating the same according to some embodiments of the present inventive concept in conjunction with the accompanying drawings.

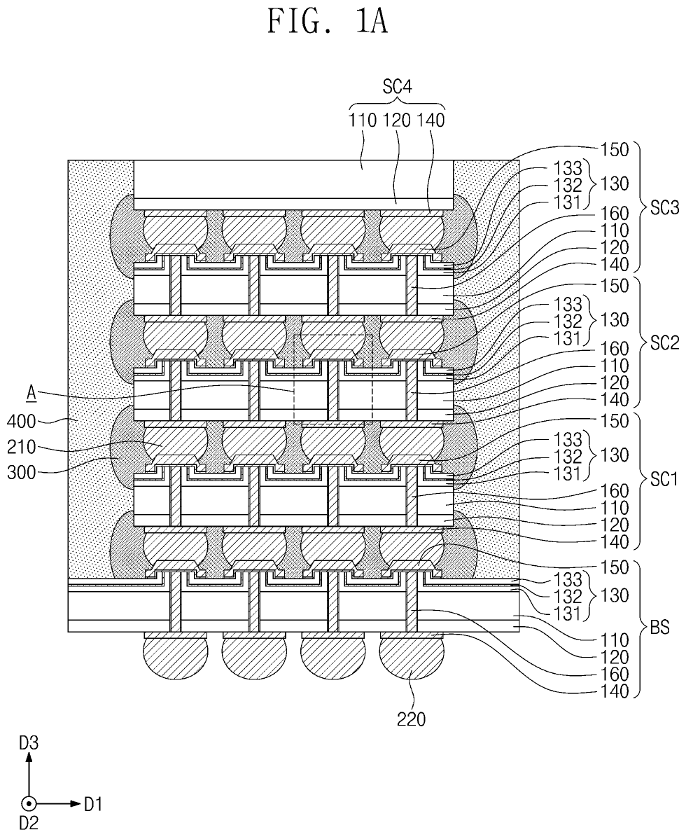

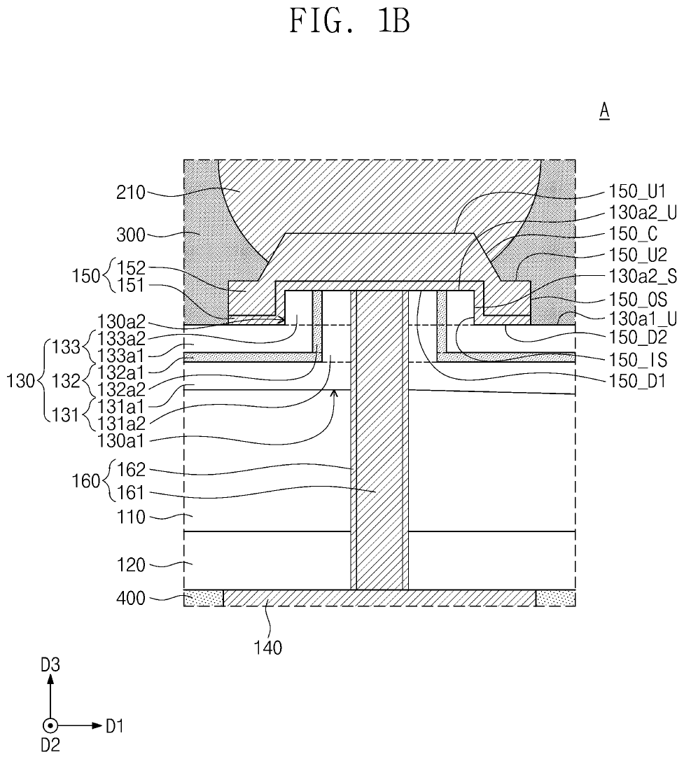

FIG. 1A is a cross-sectional view showing a semiconductor package according to some embodiments. FIG. 1B is an enlarged view showing section A of FIG. 1A.

Referring to FIGS. 1A and 1B, a semiconductor package may include a base structure BS, a first semiconductor chip SC1, a second semiconductor chip SC2, a third semiconductor chip SC3, and a fourth semiconductor chip SC4.

Each of the base structure BS, the first semiconductor chip SC1, the second semiconductor chip SC2, and the third semiconductor chip SC3 may include a substrate 110, a wiring structure 120, a dielectric structure 130, connection pads 140, pad structures 150, and via structures 160. The fourth semiconductor chip SC4 may include a substrate 110, a wiring structure 120, and connection pads 140.

The substrate 110 may have a plate shape that extends along a plane defined by a first direction D1 and a second direction D2. The first direction D1 and the second direction D2 may intersect each other. For example, the first direction D1 and the second direction D2 may be horizontal directions that are orthogonal to each other. The substrate 110 may be a semiconductor substrate. For example, the substrate 110 may include silicon, germanium, silicon-germanium, gallium-phosphorus, or gallium-arsenic. In some embodiments, the substrate 110 may be a silicon-on-insulator (SOI) substrate or a germanium-on-insulator (GOI) substrate.

The wiring structure 120 may cover a bottom surface of the substrate 110. The substrate 110 may be disposed on the wiring structure 120. The wiring structure 120 may include an electrically conductive structure and a dielectric layer that at least partially surrounds the electrically conductive structure. The electrically conductive structure of the wiring structure 120 may include an electrically conductive contact, an electrically conductive line, and/or an electrically conductive pad. The electrically conductive structure of the wiring structure 120 may be electrically connected to the connection pad 140. In some embodiments, the wiring structure 120 may include a plurality of dielectric layers.

In some embodiments, each of the base structure BS, the first semiconductor chip SC1, the second semiconductor chip SC2, the third semiconductor chip SC3, and the fourth semiconductor chip SC4 may include a semiconductor device disposed between the substrate 110 and the wiring structure 120. For example, each of the base structure BS, the first semiconductor chip SC1, the second semiconductor chip SC2, the third semiconductor chip SC3, and the fourth semiconductor chip SC4 may include a semiconductor memory element or a semiconductor logic element.

The connection pads 140 may be disposed on a bottom surface of the wiring structure 120. The connection pads 140 may be downwardly exposed electrically conductive patterns of each of the base structure BS, the first semiconductor chip SC1, the second semiconductor chip SC2, the third semiconductor chip SC3, and the fourth semiconductor chip SC4. The connection pads 140 may include an electrically conductive material. In some embodiments, the connection pads 140 may be at least partially surrounded by the wiring structure 120.

The via structure 160 may penetrate in a third direction D3 through the substrate 110, the wiring structure 120, and the dielectric structure 130, and may electrically connect the connection pad 140 to the pad structure 150. The third direction D3 may intersect the first direction D1 and the second direction D2. For example, the third direction D3 may be a vertical direction perpendicular to the first direction D1 and the second direction D2.

The via structure 160 may include an inner via 161 and an outer via 162 that at least partially surrounds the inner via 161. The via structure 160 may be disposed on the connection pad 140. The inner via 161 and the outer via 162 may be in contact with the connection pad 140.

The via structure 160 may have a width that is less than that of the pad structure 150 and that of the connection pad 140. For example, the via structure 160 may have a width equal to or less than about 10 μm. The via structure 160 may extend in the third direction D3. For example, a length in the third direction D3 of the via structure 160 may be equal to or less than about 50 μm. A thickness of the inner via 161 of the via structure 160 may be greater than that of the outer via 162 of the via structure 160. For example, the outer via 162 of the via structure 160 may have a thickness equal to or less than about 1 μm.

The inner via 161 and the outer via 162 may include an electrically conductive material. The inner via 161 and the outer via 162 may include different electrically conductive materials different each other. For example, the different electrically conductive materials of the inner via 161 and the outer via 162 may be copper (Cu) and titanium (Ti), respectively.

The dielectric structure 130 may cover a top surface of the substrate 110. The dielectric structure 130 may include a first dielectric layer 131, a second dielectric layer 132 on the first dielectric layer 131, and a third dielectric layer 133 on the second dielectric layer 132.

The first, second, and third dielectric layers 131, 132, and 133 may include their respective first parts 131a1, 132a1, and 133a1 that extend in the first direction D1, and may also include their respective second parts 131a2, 132a2, and 133a2 that extend in the third direction D3. The first part 131a1 of the first dielectric layer 131, the first part 132a1 of the second dielectric layer 132, and the first part 133a1 of the third dielectric layer 133 may be parallel along the first direction D1. The second part 132a2 of the second dielectric layer 132 may at least partially surround the second part 131a2 of the first dielectric layer 131. The second part 133a2 of the third dielectric layer 133 may at least partially surround the second part 132a2 of the second dielectric layer 132.

The first, second, and third dielectric layers 131, 132, and 133 may include a dielectric material. For example, the first and third dielectric layers 131 and 133 may include oxide. For example, the second dielectric layer 132 may include nitride.

The dielectric structure 130 may include a first part 130a1 and a second part 130a2 on the first part 130al.

The first part 130a1 of the dielectric structure 130 may be in contact with the top surface of the substrate 110. The first part 130a1 of the dielectric structure 130 may include the first part 131a1 and a portion of the second part 131a2 of the first dielectric layer 131, the first part 132a1 and a portion of the second part 132a2 of the second dielectric layer 132, and the first part 133a1 of the third dielectric layer 133.

The second part 130a2 of the dielectric structure 130 may include a portion of the second part 131a2 of the first dielectric layer 131, a portion of the second part 132a2 of the second dielectric layer 132, and the second part 133a2 of the third dielectric layer 133. The second part 130a2 of the dielectric structure 130 may be a portion that protrudes in the third direction D3 from the first part 130a1 of the dielectric structure 130.

The first part 130a1 of the dielectric structure 130 may have a top surface 130a1_U at a level that is lower than that of a top surface 130a2_U of the second part 130a2 of the dielectric structure 130. The second part 130a2 of the dielectric structure 130 may have a sidewall 130a2_S that connects the top surface 130a1_U of the first part 130a1 of the dielectric structure 130 to the top surface 130a2_U of the second part 130a2 of the dielectric structure 130.

The pad structure 150 may be disposed on the dielectric structure 130 and the via structure 160. The pad structure 150 may include a lower pad 151 and an upper pad 152 on the lower pad 151. The lower pad 151 of the pad structure 150 may be in contact with the via structure 160. The upper pad 152 of the pad structure 150 may be spaced apart from the via structure 160.

The lower pad 151 may be in contact with a top surface of the via structure 160. The lower pad 151 may be in contact with the inner via 161 and the outer via 162 of the via structure 160. The lower pad 151 may be in contact with the dielectric structure 130. The lower pad 151 may be in contact with the top surface 130a1_U of the first part 130a1 of the dielectric structure 130. The lower pad 151 may be in contact with the sidewall 130a2_S and the top surface 130a2_U of the second part 130a2 of the dielectric structure 130. The upper pad 152 may be in contact with a bump 210 which will be discussed below. The upper pad 152 may have a thickness that is greater than that of the lower pad 151. For example, the lower pad 151 may have a thickness of equal to or less than about 1 μm.

The lower pad 151 and the upper pad 152 may include an electrically conductive material. The lower pad 151 and the upper pad 152 may include different electrically conductive materials from each other. For example, the different electrically conductive materials of the lower pad 151 and the upper pad 152 may be copper (Cu) and titanium (Ti), respectively.

The base structure BS, the first semiconductor chip SC1, the second semiconductor chip SC2, the third semiconductor chip SC3, and the fourth semiconductor chip SC4 may be sequentially arranged along the third direction D3. The base structure BS may have a width that is greater than those of the first, second, third, and fourth semiconductor chips SC1, SC2, SC3, and SC4. For example, a width in the first direction D1 of the base structure BS may be greater than a width in the first direction D1 of each of the first, second, third, and fourth semiconductor chips SC1, SC2, SC3, and SC4. In some embodiments, the base structure BS may be a redistribution substrate including redistribution patterns.

The semiconductor package may further include bumps 210. The bump 210 may be provided between the base structure BS and the first semiconductor chip SC1, between the first semiconductor chip SC1 and the second semiconductor chip SC2, between the second semiconductor chip SC2 and the third semiconductor chip SC3, and/or between the third semiconductor chip SC3 and the fourth semiconductor chip SC4. The bump 210 may connect the base structure BS and the first, second, third, and fourth semiconductor chips SC1, SC2, SC3, and SC4 to each other. The bump 210 may include an electrically conductive material. For example, the bump 210 may include copper and/or nickel.

The semiconductor package may further include terminals 220. The terminal 220 may be connected to the connection pad 140 of the base structure BS. The semiconductor package may be electrically connected through the terminal 220 to an external apparatus. The terminal 220 may include an electrically conductive material.

The semiconductor package may further include adhesion layers 300. The adhesion layers 300 may be disposed on the base structure BS, the first semiconductor chip SC1, the second semiconductor chip SC2, and the third semiconductor chip SC3. The adhesion layers 300 may be arranged along the third direction D3. The adhesion layers 300 may be disposed between the base structure BS and the first semiconductor chip SC1, between the first semiconductor chip SC1 and the second semiconductor chip SC2, between the second semiconductor chip SC2 and the third semiconductor chip SC3, and between the third semiconductor chip SC3 and the fourth semiconductor chip SC4.

The adhesion layer 300 may include an adhesive polymer material. For example, the adhesion layer 300 may include a non-conductive film (NCF).

The semiconductor package may further include a molding layer 400 on the base structure BS. The molding layer 400 may at last partially surround the first, second, third, and fourth semiconductor chips SC1, SC2, SC3, and SC4 and the bumps 210. The molding layer 400 may include a polymer material. For example, the molding layer 400 may include an epoxy molding compound (EMC).

The pad structure 150 may include a first top surface 150_U1, a second top surface 150_U2, a connection surface 150_C, a first bottom surface 150_D1, a second bottom surface 150_D2, an outer sidewall 150_OS, and an inner sidewall 150_IS.

The first top surface 150_U1 of the pad structure 150 may be in contact with the bump 210. The second top surface 150_U2 of the pad structure 150 may be disposed at a level that is lower than that of the first top surface 150_U1 of the pad structure 150. The connection surface 150_C of the pad structure 150 may connect the first top surface 150_U1 of the pad structure 150 to the second top surface 150_U2 of the pad structure 150. The first bottom surface 150_D1 of the pad structure 150 may be in contact with the via structure 160. The first bottom surface 150_D1 of the pad structure 150 may be in contact with the top surface 130a2_U of the second part 130a2 of the dielectric structure 130. The second bottom surface 150_D2 of the pad structure 150 may be disposed at a level that is lower than that of the first bottom surface 150_D1 of the pad structure 150. The second bottom surface 150_D2 of the pad structure 150 may be in contact with the top surface 130a1_U of the first part 130a1 of the dielectric structure 130. The outer sidewall 150_OS of the pad structure 150 may connect the second top surface 150_U2 of the pad structure 150 to the second bottom surface 150_D2 of the pad structure 150. The inner sidewall 150_IS of the pad structure 150 may connect the first bottom surface 150_D1 of the pad structure 150 to the second bottom surface 150_D2 of the pad structure 150.

The second top surface 150_U2 of the pad structure 150 may be disposed at a level that is higher than that of the first bottom surface 150_D1 of the pad structure 150. The second top surface 150_U2 of the pad structure 150 may be disposed at a level that is higher than that of the top surface of the via structure 160. The second bottom surface 150_D2 of the pad structure 150 may be disposed at a level that is lower than that of the top surface of the via structure 160 and that of the top surface 130a2_U of the second part 130a2 of the dielectric structure 130. A distance between the first top surface 150_U1 and the first bottom surface 150_D1 of the pad structure 150 may be equal to a distance between the second top surface 150_D2 and the second bottom surface 150_D2 of the pad structure 150.

The connection surface 150_C of the pad structure 150 may be in contact with the bump 210 and the adhesion layer 300. The connection surface 150_C of the pad structure 150 may be connected to the bump 210. The connection surface 150_C of the pad structure 150 may be inclined. The connection surface 150_C of the pad structure 150 may be flat. For example, an angle of between 90° and 180° may be made between the first top surface 150_U1 and the connection surface 150_C of the pad structure 150. For example, an angle of between 90° and 180° may be made between the second top surface 150_U2 and the connection surface 150_C of the pad structure 150.

The outer sidewall 150_OS of the pad structure 150 may be parallel to the inner sidewall 150_IS of the pad structure 150. A length in the third direction D3 of the outer sidewall 150_OS of the pad structure 150 may be greater than a length in the third direction D3 of the inner sidewall 150_IS of the pad structure 150. The length in the third direction D3 of the outer sidewall 150_OS of the pad structure 150 may be less than the length in the third direction D3 of the via structure 160. A width in the first direction D1 of the first bottom surface 150_D1 of the pad structure 150 may be greater than a width in the first direction D1 of the via structure 160.

The inner sidewall 150_IS of the pad structure 150 may be a sidewall of the second part 130a2 of the dielectric structure 130. The first bottom surface 150_D1 of the pad structure 150 may be the top surface 130a2_U of the second part 130a2 of the dielectric structure 130 and the top surface of the via structure 160. The second bottom surface 150_D2 of the pad structure 150 may be the top surface 130a1_U of the first part 130a1 of the dielectric structure 130.

The dielectric structure 130 may be interposed between the via structure 160 and the pad structure 150. The second part 130a2 of the dielectric structure 130 may be interposed between the via structure 160 and the inner sidewall 150_IS of the pad structure 150. The second part 130a2 of the dielectric structure 130 may be in contact with the via structure 160, the inner sidewall 150_IS of the pad structure 150, and the first bottom surface 150_D1 of the pad structure 150. The second part 130a2 of the dielectric structure 130 may at least partially surround the via structure 160. The pad structure 150 may at least partially surround the second part 130a2 of the dielectric structure 130.

The first part 130a1 of the dielectric structure 130 may be in contact with the second bottom surface 150_D2 of the pad structure 150. The top surface 130a2_U of the second part 130a2 of the dielectric structure 130 may be coplanar with the top surface of the via structure 160. The top surface 130a2_U of the second part 130a2 of the dielectric structure 130 may be disposed at the same level as that of a top surface of the inner via 161 of the via structure 160 and that of a top surface of the outer via 162 of the via structure 160.

In a semiconductor package, according to some embodiments, as the dielectric structure 130 includes the second part 130a2, the pad structure 150 on the dielectric structure 130 may include the first top surface 150_U1, the second top surface 150_U2 disposed at a level that is lower than that of the first top surface 150_U1, and the connection surface 150_C disposed at a level that is lower than that of the first top surface 150_U1. As the pad structure 150 includes the first top surface 150_U1 at a level higher than that of the second top surface 150_U2, the bump 210 contact the first top surface 150_U1 ahead of the second top surface 150_U2. There may thus be a reduction in initial contact area between the bump 210 and the pad structure 150 and an increase in force applied to the bump 210. Accordingly, the bump 210 may penetrate the adhesion layer 300 to contact the pad structure 150, and thus it may be possible to mitigate a non-wet phenomenon and to increase electrical properties of the semiconductor package.

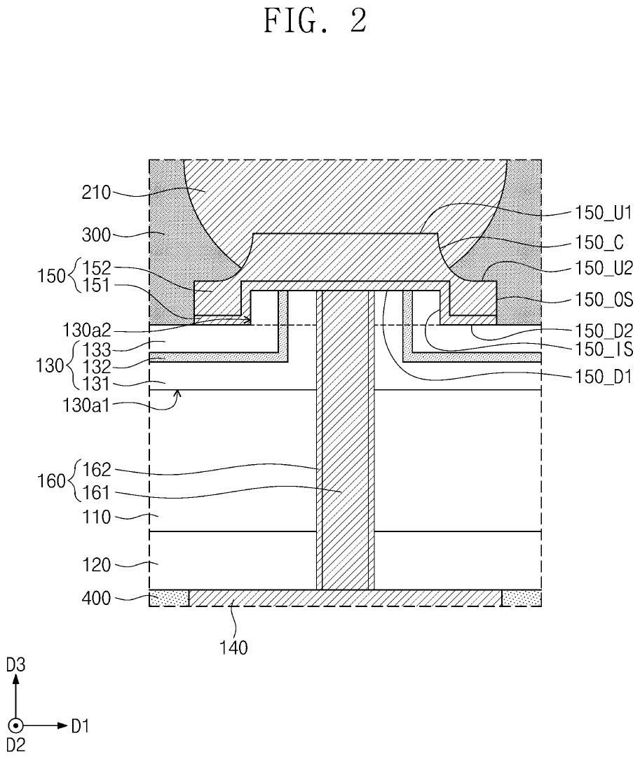

FIG. 2 illustrates an enlarged cross-sectional view showing a semiconductor package according to some embodiments.

Referring to FIG. 2, a semiconductor package may include a via structure 160, a pad structure 150, a bump 210, and an adhesion layer 300. The pad structure 150 may include a first top surface 150_U1, a second top surface 150_U2, and a connection surface 150_C.

The pad structure 150 may be flat at the first top surface 150_U1 and the second top surface 150_U2. The pad structure 150 may be curved at the connection surface 150_C. In some embodiments, the pad structure 150 may be curved at the second top surface 150_U2.

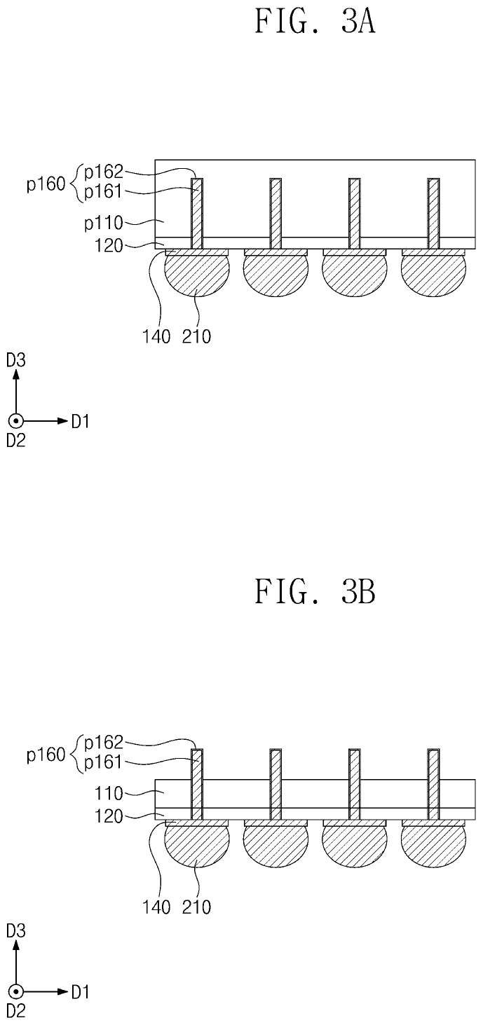

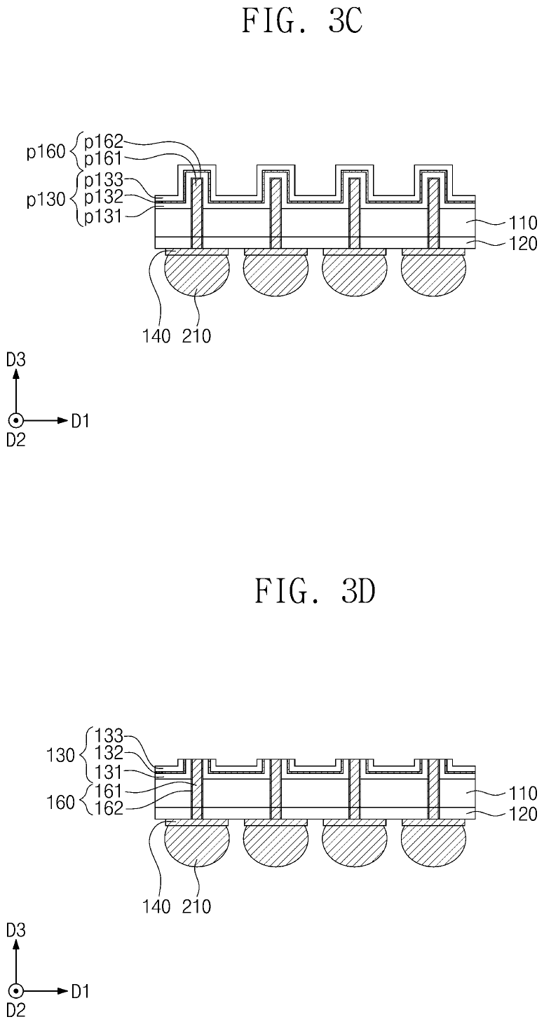

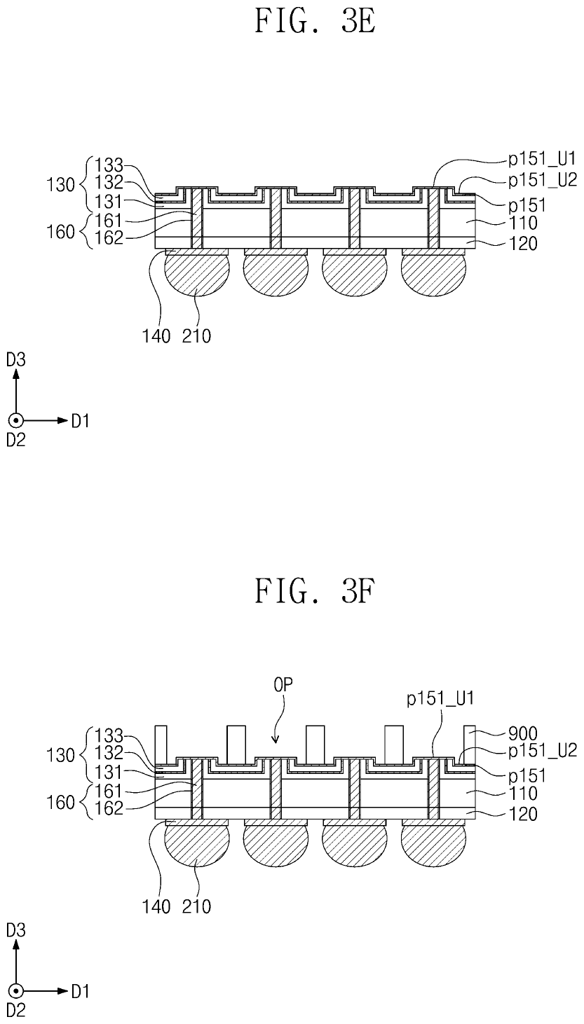

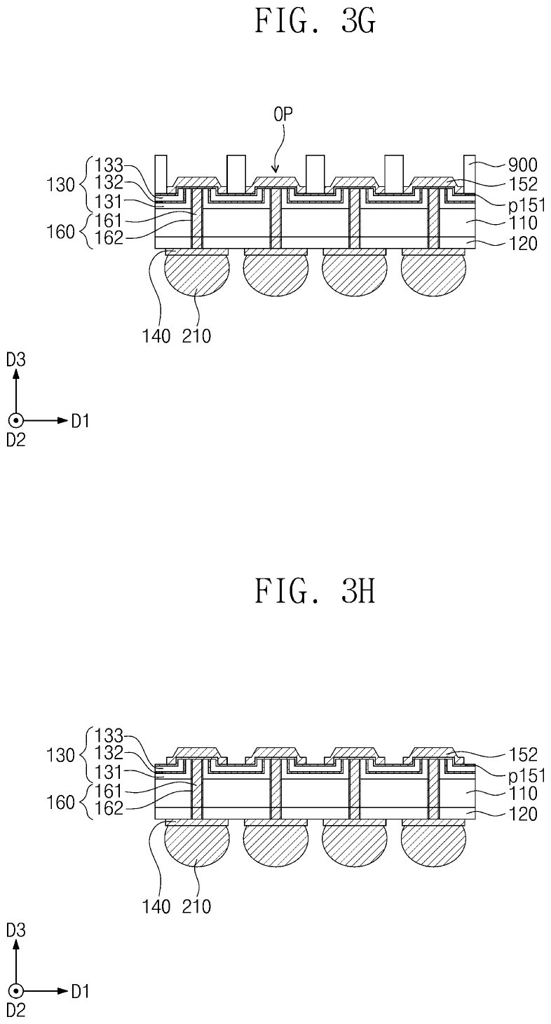

FIGS. 3A to 31 illustrate cross-sectional views showing a method of fabricating a semiconductor package according to FIG. 1A.

Referring to FIG. 3A, a bump 210 may be formed, a connection pad 140 may be formed on the bump 210, a wiring structure 120 may be formed on the connection pad 140, a preliminary substrate p110 may be formed on the wiring structure 120, and a preliminary via structure p160 may be at least partially surrounded by the preliminary substrate p110. The preliminary via structure p160 may be disposed on the connection pad 140. The preliminary via structure p160 may include a preliminary inner via p161 and a preliminary outer via p162 that at least partially surrounds the preliminary inner via p161. The preliminary outer via p162 may be at least partially surrounded by the wiring structure 120 and the preliminary substrate p110.

Referring to FIG. 3B, a portion of the preliminary substrate p110 may be removed to form a substrate 110. A portion of the preliminary substrate p110 may be removed to expose a portion of the preliminary via structure p160. The portion of the preliminary substrate p110 may be removed by, for example, an etching process.

Referring to FIG. 3C, a preliminary dielectric structure p130 may be formed on a top surface of the substrate 110 and the exposed portion of the preliminary via structure p160. The preliminary dielectric structure p130 may include first, second, and third preliminary dielectric layers p131, p1132, and p133. The first, second, and third preliminary dielectric layers p131, p1132, and p133 may be sequentially formed. The first, second, and third preliminary dielectric layers p131, p132, and p133 may be formed by, for example, a chemical vapor deposition (CVD) process. The first, second, and third preliminary dielectric layers p131, p132, and p133 may include a dielectric material. The second preliminary dielectric layer p132 may include a different dielectric material from that of the first and third preliminary dielectric layers p131 and p133. For example, the second preliminary dielectric layer p132 may include nitride, and the first and third preliminary dielectric layers p131 and p133 may include oxide.

Referring to FIG. 3D, a portion of the preliminary dielectric structure p130 may be removed to form a dielectric structure 130 including first, second, and third dielectric layers 131, 132, and 133. A portion of the preliminary via structure p160 may be removed to form a via structure 160 including an inner via 161 and an outer via 162 that at least partially surrounds the inner via 161. A chemical mechanical polishing (CMP) process may be employed to remove the portion of the first, second, and third preliminary dielectric layers p131, p132, and p133 and the portion of the preliminary via structure p160.

The partial removal of the first, second, and third preliminary dielectric layers p131, p132, and p133 may form a first part (see 130a1 of FIG. 2) of the dielectric structure 130 and a second part (see 130a2 of FIG. 2) on the first part 130al. The partial removal of the first, second, and third preliminary dielectric layers p131, p132, and p133 may expose a top surface of the second part 130a2 of the dielectric structure 130 and a top surface of the via structure 160. In the dielectric structure 130, the exposure of the top surface of the second part 130a2 may mean that a top surface of each of the first, second, and third dielectric layers 131, 132, and 133 may be exposed in a third direction D3.

The portion of the preliminary via structure p160 may be removed to expose the top surface of the via structure 160. The exposure of the top surface of the via structure 160 may mean that top surfaces of the inner and outer vias 161 and 162 are exposed.

Referring to FIG. 3E, a preliminary lower pad p151 may be formed on the dielectric structure 130 and the via structure 160. The preliminary lower pad p151 may be formed by, for example, a physical vapor deposition (PVD) process.

The preliminary lower pad p151 may have first and second top surfaces p151_U1 and p151_U2. The first top surface p151_U1 of the preliminary lower pad p151 may be disposed at a level that is higher than that of the second top surface p151_U2 of the preliminary lower pad p151. The first top surface p151_U1 of the preliminary lower pad p151 may be formed on the via structure 160 and the second part 130a2 of the dielectric structure 130. The second top surface p151_U2 of the preliminary lower pad p151 may be formed on the first part 130a1 of the dielectric structure 130.

Referring to FIG. 3F, a photoresist layer 900 may be formed on the second top surface p151_U2 of the preliminary lower pad p151. The photoresist layer 900 may include an opening OP that exposes the second top surface p151_U2 of the preliminary lower pad p151. The opening OP may further expose a portion of the second top surface p151_U2 of the preliminary lower pad p151. A photolithography process may be used to form the opening OP of the photoresist layer 900.

Referring to FIG. 3G, an upper pad 152 may be formed. The upper pad 152 may be formed in the opening OP. The upper pad 152 may be formed on the first top surface p151_U1 of the preliminary lower pad p151 exposed through the opening OP. The upper pad 152 may also be formed on the exposed portion of the second top surface p151_U2 of the preliminary lower pad p151. The upper pad 152 may be formed by, for example, a physical vapor deposition (PVD) process.

Referring to FIG. 3H, the photoresist layer 900 may be removed. The removal of the photoresist layer 900 may expose a portion of the second top surface p151_U2 of the preliminary lower pad p151.

Referring to FIG. 3I, a portion of the preliminary lower pad p151 may be removed. The partial removal of the preliminary lower pad p151 may form a lower pad 151. The portion of the preliminary lower pad p151 may be removed by, for example, an etching process. The formation of the lower pad 151 may form a first semiconductor chip SC1 on the bump 210. The lower pad 151 and the upper pad 152 may constitute a pad structure 150.

Referring back to FIG. 1A, a process similar to that used for forming the first semiconductor chip SC1 may be performed to form a base structure BS, a second semiconductor chip SC2, a third semiconductor chip SC3, and a fourth semiconductor chip SC4.

Adhesion layers 300 may be formed between the base structure BS and the first semiconductor chip SC1, between the first semiconductor chip SC1 and the second semiconductor chip SC2, between the second semiconductor chip SC2 and the third semiconductor chip SC3, and between the third semiconductor chip SC3 and the fourth semiconductor chip SC4.

A molding layer 400 may at least partially surround the base structure BS, the first, second, third, and fourth semiconductor chips SC1, SC2, SC3, and SC4, and the adhesion layers 300.

In a method of forming a semiconductor package, according to some embodiments, a portion of the preliminary dielectric structure p130 and a portion of the preliminary via structure p160 may be removed to form the dielectric structure 130 and the via structure 160 each of which has a protruding shape. As the dielectric structure 130 and the via structure 160 have the protruding shape, the pad structure 150 formed on the dielectric structure 130 and the via structure 160 may also have a protruding shape. As the pad structure 150 has the protruding shape, a step difference may be formed between a first top surface (see 150_U1 of FIG. 2) and a second top surface (see 150_U2 of FIG. 2) of the pad structure 150, and a connection surface 150_C may be formed which connects the first top surface 150_U1 to the second top surface 150_U2.

FIG. 4 illustrates a cross-sectional view showing a semiconductor package according to some embodiments.

Referring to FIG. 4, a semiconductor package may include a package substrate 820b. For example, the package substrate 820b may be a printed circuit board. First terminals 810b may be provided which are electrically connected to the package substrate 820b. The semiconductor package may be mounted through first terminals 810b on an external apparatus (e.g., a mainboard).

An interposer 840b may be disposed on the package substrate 820b. Second terminals 830b may electrically connect the package substrate 820b and the interposer 840b to each other. The second terminals 830b may be disposed between the package substrate 820b and the interposer 840b.

A processor chip 860b may be disposed on the interposer 840b. For example, the processor chip 860b may be a graphic processing unit (GPU) or a central processing unit (CPU). Third terminals 850b may electrically connect the processor chip 860b to the interposer 840b. The third terminals 850b may be provided between the processor chip 860b and the interposer 840b.

The interposer 840b may be provided thereon with a base structure BSb and first, second, third, and fourth semiconductor chips SC1b, SC2b, SC3b, and SC4b that are sequentially disposed along a third direction D3. The base structure BSb and the first, second, third, and fourth semiconductor chips SC1b, SC2b, SC3b, and SC4b may each be a semiconductor chip including a logic element or a memory element. Bumps 210b may be provided between the base structures BSb and the first, second, third, and fourth semiconductor chips SC1b, SC2b, SC3b, and SC4b. Adhesion layers 300b may be provided between the base structures BSb, the first, second, third, and fourth semiconductor chips SC1b, SC2b, SC3b, and SC4b, and the bumps 210b. The base structure BSb, the first to fourth semiconductor chips SC1b, SC2b, SC3b, and SC4b, the bumps 210b, and the adhesion layers 300b may be similar to the base structure BS, the first to fourth semiconductor chips SC1, SC2, SC3, and SC4, the bumps 210, and the adhesion layers 300 of FIG. 1A.

First terminals 220b may electrically connect the base structure BSb to the interposer 840b. The first terminals 220b may be provided between the base structure BSb and the interposer 840b. A first molding layer 400b may at least partially surround the base structures BSb, the first to fourth semiconductor chips SC1b, SC2b, SC3b, and SC4b, and the adhesion layers 300b. A second molding layer 460b may at least partially surround the interposer 840b, the processor chip 860b, the base structure BSb, and the first to fourth semiconductor chips SC1b, SC2b, SC3b, and SC4b.

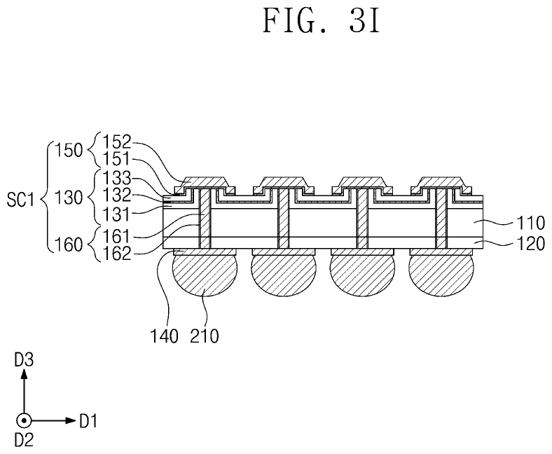

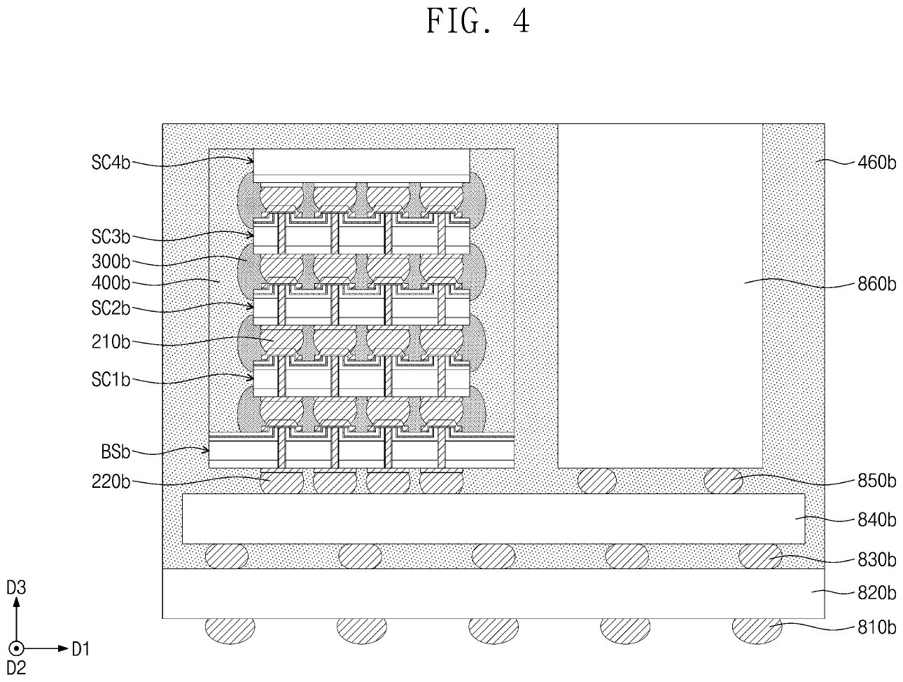

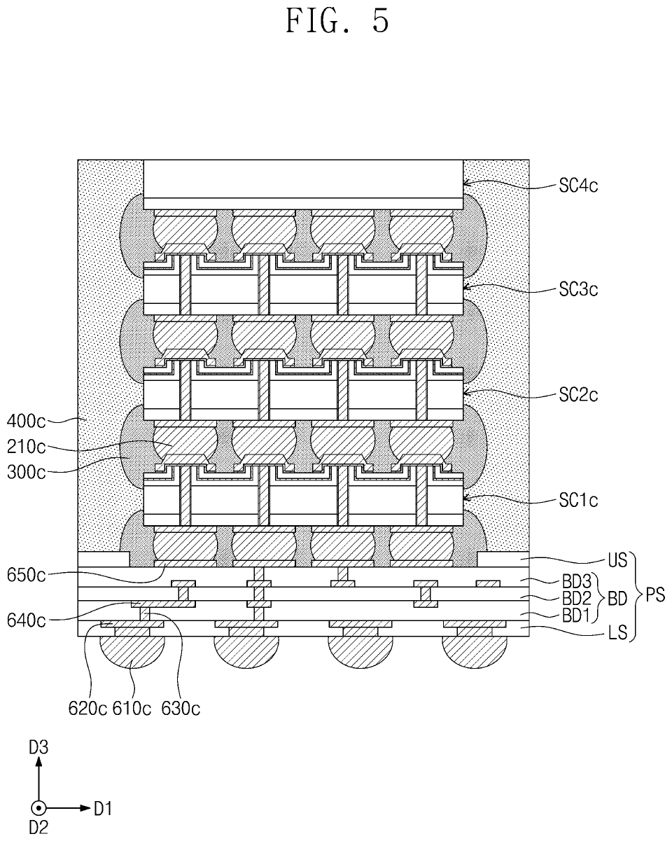

FIG. 5 illustrates a cross-sectional view showing a semiconductor package according to some embodiments.

Referring to FIG. 5, a semiconductor package may include a printed circuit board PS, first to fourth semiconductor chips SC1c, SC2c, SC3c, and SC4c, solder balls 610c, bumps 210c, adhesion layers 300c, and a molding layer 400c.

The printed circuit board PS may be disposed on the solder balls 610c. The printed circuit board PS may be provided thereon with the first, second, third, and fourth semiconductor chips SC1c, SC2c, SC3c, and SC4c that are sequentially disposed along a third direction D3. The first, second, third, and fourth semiconductor chips SC1c, SC2c, SC3c, and SC4c may each be a semiconductor chip including a logic element or a memory element. The bumps 210c may be provided between the first, second, third, and fourth semiconductor chips SC1c, SC2c, SC3c, and SC4c. The adhesion layers 300c may be provided between the first, second, third, and fourth semiconductor chips SC1c, SC2c, SC3c, and SC4c and the bumps 210c. The molding layer 400c may at least partially surround the printed circuit board PS, the adhesion layers 300c, and the first, second, third, and fourth semiconductor chips SC1c, SC2c, SC3c, and SC4c.

The first to fourth semiconductor chips SC1c, SC2c, SC3c, and SC4c, the bumps 210c, the adhesion layers 300c, and the molding layer 400c may be similar to the first to fourth semiconductor chips SC1, SC2, SC3, and SC4, the bumps 210, the adhesion layers 300, and the molding layer 400 of FIG. 1A.

The printed circuit board PS may include a lower dielectric layer LS, a body part BD on the lower dielectric layer LS, an upper dielectric layer US on the body part BD, first and second pads 620c and 650c, electrically conductive patterns 640c, and vias 630c. The printed circuit board PS may connect a semiconductor chip to an external apparatus.

The body part BD may include a dielectric material. The body part BD may include a thermosetting resin such as an epoxy resin, a thermoplastic resin such as polyimide, a resin (e.g., prepreg) in which a thermosetting or thermoplastic resin is impregnated with a stiffener such as glass fiber and inorganic fillers, or photo-curable resins, but the present inventive concepts are not necessarily limited thereto.

The body part BD may include a plurality of substrate dielectric layers BD1, BD2, and BD3. The plurality of substrate dielectric layers BD1, BD2, and BD3 may be sequentially stacked along the third direction D3. A second substrate dielectric layer BD2 may be disposed on a first substrate dielectric layer BD1, and a third substrate dielectric layer BD3 may be disposed on the second substrate dielectric layer BD2. The number of the substrate dielectric layers BD1, BD2, and BD3 might not necessarily be limited to that shown.

The lower dielectric layer LS may be disposed on a bottom surface of the first substrate dielectric layer BD1 in the body part BD. The upper dielectric layer US may be disposed on a top surface of the third substrate dielectric layer BD3 in the body part BD. The lower dielectric layer LS and the upper dielectric layer US may include a dielectric polymer material. For example, the lower dielectric layer LS and the upper dielectric layer US may include a solder resist material. The solder resist material may include epoxy or acrylate. The lower dielectric layer LS and the upper dielectric layer US may protect the body part BD from ambient contaminants. The upper dielectric layer US may be in contact with the adhesion layer 300c. In some embodiments, the upper dielectric layer US may be spaced apart from the adhesion layer 300c.

The electrically conductive patterns 640c and the vias 630c may be disposed in the body part BD. The electrically conductive patterns 640c may be disposed in the body part BD. The electrically conductive patterns 640c may be at least partially surrounded by the first, second, and third substrate dielectric layers BD1, BD2, and BD3. The electrically conductive patterns 640c may each have a pad shape and/or a line shape. The vias 630c may be provided in the body part BD. The vias 630c may be at least partially surrounded by the first, second, and third substrate dielectric layers BD1, BD2, and BD3.

The first pads 620c may be disposed on the first substrate dielectric layer BD1 of the body part BD. The second pads 650c may be disposed on the third substrate dielectric layer BD3 of the body part BD. The first pads 620c may be exposed downwardly from the body part BD. The second pads 650c may be exposed upwardly from the body part BD. The first pads 620c may be in contact with the solder balls 610c. The second pads 650c may be in contact with the bumps 210c.

The first and second pads 620c and 650c, the electrically conductive patterns 640c, and the vias 630c may include an electrically conductive material. For example, the first and second pads 620c and 650c, the electrically conductive patterns 640c, and the vias 630c may include copper (Cu).

The solder balls 610c may be provided on the first pads 620c. The semiconductor package may be electrically connected through the solder balls 610c to an external apparatus. The solder balls 610c may include an electrically conductive material.

The solder ball 610c may be connected to the first pad 620c. The first pad 620c may be connected through the via 630c to the electrically conductive pattern 640c. The via 630c may connect the electrically conductive patterns 640c to each other. The second pad 650c may be connected through the via 630c to the electrically conductive pattern 640c. The first to fourth semiconductor patterns SC1c, SC2c, SC3c, and SC4c may be electrically connected to the vias 630c through the bumps 210c and the second pads 650c.

In a semiconductor package, according to some embodiments of the present inventive concepts, because a pad structure has a first top surface, a second top surface at a level that is lower than that of the first top surface, and a connection surface, an initial contact area between a bump and the pad structure may be reduced to mitigate a non-wet phenomenon.

Although embodiments of the present invention have been described in connection with the accompanying drawings, it will be understood by one of ordinary skill in the art that variations in form and detail may be made therein without departing from the spirit and essential feature of the present inventive concepts.

What is claimed is:

1. A semiconductor package, comprising:
a substrate;
a dielectric structure disposed on the substrate;
a via structure that penetrates the substrate and the dielectric structure; and
a pad structure disposed on the via structure,
wherein the pad structure includes:
a first bottom surface that is in contact with the via structure;
a second bottom surface at a level that is lower than a level of the first bottom surface; and
an inner sidewall that connects the first bottom surface to the second bottom surface,
wherein a portion of the dielectric structure is disposed between the via structure and the inner sidewall of the pad structure.

2. The semiconductor package of claim 1, wherein the pad structure further includes:
a first top surface;
a second top surface at a level that is lower than a level of the first top surface; and
a connection surface that connects the first top surface to the second top surface.

3. The semiconductor package of claim 2, wherein the level of the second top surface of the pad structure is higher than the level of the first bottom surface of the pad structure.

4. The semiconductor package of claim 2, wherein the connection surface of the pad structure is inclined.

5. The semiconductor package of claim 2, wherein the connection surface of the pad structure is flat.

6. The semiconductor package of claim 2, wherein the connection surface of the pad structure is curved.

7. The semiconductor package of claim 2, further comprising a bump that is in contact with the pad structure,
wherein the bump is in contact with the connection surface of the pad structure.

8. The semiconductor package of claim 2, wherein a distance between the first top surface and the first bottom surface of the pad structure is equal to a distance between the second top surface and the second bottom surface of the pad structure.

9. The semiconductor package of claim 1, wherein the pad structure further has an outer sidewall that is parallel to the inner sidewall,
wherein a length of the outer sidewall is greater than a length of the inner sidewall.

10. The semiconductor package of claim 1, wherein the level of the second bottom surface of the pad structure is lower than a level of a top surface of the via structure.

11. The semiconductor package of claim 1, wherein the pad structure includes a lower pad and an upper pad disposed on the lower pad,
wherein the lower pad is in contact with the via structure, and
wherein the upper pad is spaced apart from the via structure.

12. The semiconductor package of claim 11, wherein the lower and upper pads of the pad structure include different electrically conductive materials from each other.

13. A semiconductor package, comprising:
a substrate;
a dielectric structure disposed on the substrate;
a via structure that penetrates the substrate and the dielectric structure; and
a pad structure that is in contact with the via structure,
wherein the dielectric structure includes a first part and a second part disposed on the first part,
wherein the second part of the dielectric structure is disposed between the via structure and the pad structure, and
wherein a top surface of the second part of the dielectric structure is coplanar with a top surface of the via structure.

14. The semiconductor package of claim 13, wherein the pad structure includes:
a first bottom surface that is in contact with the via structure;
a second bottom surface at a level that is lower than a level of the first bottom surface; and
an inner sidewall that connects the first bottom surface to the second bottom surface.

15. The semiconductor package of claim 14, wherein the second part of the dielectric structure is in contact with both the first bottom surface and the inner sidewall of the pad structure.

16. The semiconductor package of claim 13, wherein the via structure includes an inner via and an outer via that at least partially surrounds the inner via,
wherein a top surface of the inner via and a top surface of the outer via are at a level equal to a level of the top surface of the second part included in the dielectric structure.

17. The semiconductor package of claim 13, wherein the dielectric structure includes a first dielectric layer, a second dielectric layer disposed on the first dielectric layer, and a third dielectric layer disposed on the second dielectric layer.

18. The semiconductor package of claim 13, wherein
the second part of the dielectric structure at least partially surrounds the via structure, and
the pad structure at least partially surrounds the second part of the dielectric structure.

19. A semiconductor package, comprising:
a substrate;
a dielectric structure disposed on the substrate;
a via structure that penetrates the substrate and the dielectric structure;
a pad structure disposed on the via structure; and
a bump that is in contact with the pad structure,
wherein the dielectric structure includes a first part and a second part disposed on the first part,
wherein the pad structure includes:
a first bottom surface that is in contact with the via structure;
a second bottom surface at a level that is lower than a level of the first bottom surface; and
an inner sidewall that connects the first bottom surface to the second bottom surface,
wherein the first part of the dielectric structure is in contact with the second bottom surface of the pad structure,
wherein the second part of the dielectric structure is in contact with the inner sidewall of the pad structure and the first bottom surface of the pad structure, and
wherein the via structure is in contact with the first bottom surface of the pad structure.

20. The semiconductor package of claim 19, wherein the pad structure further has a first top surface and a second top surface at a level that is lower than a level of the first top surface,
wherein the level of the second top surface of the pad structure is higher than a level of a top surface of the via structure.

21. A method of fabricating a semiconductor package, the method comprising:
forming a preliminary substrate;
forming a preliminary via structure at least partially surrounded by the preliminary substrate;
removing a portion of the preliminary substrate to expose the preliminary via structure;
forming a preliminary dielectric structure disposed on the preliminary via structure;
removing a portion of the preliminary dielectric structure and a portion of the preliminary via structure to form a dielectric structure and a via structure; and
forming a pad structure on the dielectric structure and the via structure,
wherein the dielectric structure includes a first part and a second part, and
wherein the second part of the dielectric structure is at least partially surrounded by the pad structure.

22. The method of claim 21, wherein removing the portion of the preliminary dielectric structure and the portion of the preliminary via structure includes performing a chemical mechanical polishing process on the preliminary dielectric structure and the preliminary via structure to expose a top surface of the second part of the dielectric structure and a top surface of the via structure.

23. The method of claim 21, wherein forming the pad structure includes:
forming a preliminary lower pad that covers both a top surface of the via structure and the dielectric structure;
forming a photoresist layer on the preliminary lower pad;
forming an opening in the photoresist layer to expose the preliminary lower pad;
forming an upper pad in the opening; and
removing a portion of the preliminary lower pad to form a lower pad.

24. The method of claim 23, wherein forming the preliminary lower pad includes forming, on the via structure, a first lower pad top surface and a second lower pad top surface at a level that is lower than a level of the first bottom pad top surface.

25. The method of claim 21, further comprising:
forming a bump that is in contact with the pad structure; and
forming an adhesion layer that covers the pad structure and the bump.
